(19) United States
(12) Patent Application Publication
(10) Pub. No.: US 2005/0103798 A1
(43) Pub. Date: May 19, 2005

(54) One-way degassing valve for airtight containers for products that develop gas

(76) Inventor: Goglio Luigi, Milano (IT)

Correspondence Address: SHERIDAN ROSS PC, 1560 BROADWAY, SUITE 1200, DENVER, CO, 80202, US

(21) Appl. No.: 10/989,586

(22) Filed: Nov. 15, 2004

(30) Foreign Application Priority Data
Nov. 18, 2003 (IT) MI2003A 002238

(51) Int. Cl. B67D 5/00; H01L 29/51; H01L 29/74; H01L 31/111

(52) U.S. Cl. 222/3

(57) ABSTRACT

A one-way extra-flat degassing valve (4) for airtight containers (1) comprises: a base body or plate (5) with a first hole (52) with a smaller diameter for passage of the gases and a second hole (53) with a larger diameter for expansion of the gases; a cap (6) provided with an outlet hole (65) for discharge of gas designed to be coupled to the base body (5), and a mobile diaphragm (7) interposed between the base body (5) and the cap (6) to open/shut off the passage of gas from the second expansion hole (53) to the outlet hole (65).

The present invention refers to a one-way valve for containers for products that develop gas, in particular powder or granular products, such as coffee, food products in general, detergents and the like.

Valves of the aforesaid type are obviously already known and are commonly called one-way degassing valves. They are one-way valves which are normally applied to the top wall of the container, and serve to allow the gases developed by the product, for example coffee, to escape from the container, avoiding the formation of possible internal overpressures, which would cause bulging and/or bursting of said container, and at the same time to prevent air from entering the container as this would prejudice the quality of the product.

The one-way valves currently used achieve this object by opening when slight internal overpressures occur and closing again immediately when the overpressure ceases, or at a more reduced pressure.

Said valves present problems of structure and assembly which prevent them from being very flat. They also have defects which compromise their correct operation. Furthermore, their machinability for the application proves more complex and sometimes more uncertain.

Above all, however, because of the number of components placed on top of one another, the shape thereof and the materials used, the valves of the prior art are of considerable thickness, causing an increase in the bulk of the container and therefore greater difficulties in packaging, in contrast with the most recent demands of the market.

Among the critical points, said valves have a diaphragm consisting of a rubber cap which rests on silicone oil to make a better seal. It happens that the rubber cap, in the long term, absorbs the silicone oil and therefore swells, making uncertain the leaf values with which the valves must operate.

The object of the invention to avoid said drawbacks, by providing a degassing valve that is not bulky, is substantially flat in shape, and is thin.

Another object of the present invention is to provide such a degassing valve that is cheap and simple to assemble and produce.

Yet another object of the present invention is to provide such a degassing valve that is sufficiently rigid and therefore extremely reliable and effective.

These objects are achieved, in accordance with the invention, with the characteristics listed in independent claim 1.

Advantageous embodiments of the invention are apparent from the dependent claims.

The degassing valve for airtight containers for products that develop gas according to the invention comprises:
a base body or plate provided with an inlet hole for passage of gas,
a cap provided with a discharge hole for release of gas, designed to be coupled to the base body, and
a mobile diaphragm interposed between the base body and the cap to open/shut off the passage of gas from the inlet hole to the discharge hole.

A peculiar characteristic of the invention is represented by the fact that the base body consists of at least one flattened plate and the inlet hole comprises a first hole with a smaller diameter and a second hole with a larger diameter. The diaphragm is disposed on the base body so as to cover the hole with the larger diameter. In this manner the hole with the larger diameter forms an expansion chamber for the gas coming from the inside of the container, which tends to raise the diaphragm in order to escape to the outside through the discharge hole in the cap.

Precisely thanks to the provision of a base body with two holes of different diameters for the passage of the gases, it is possible to flatten the valve structure so as to obtain an extremely thin valve, without compromising operation thereof. Flattening of the valve is further aided by the materials used for the base body, preferably cardboard, which is coupled during assembly.

Further characteristics of the invention will be made clearer by the detailed description that follows, referring to a purely exemplifying and therefore non-limiting embodiment thereof, illustrated in the appended drawings, in which:

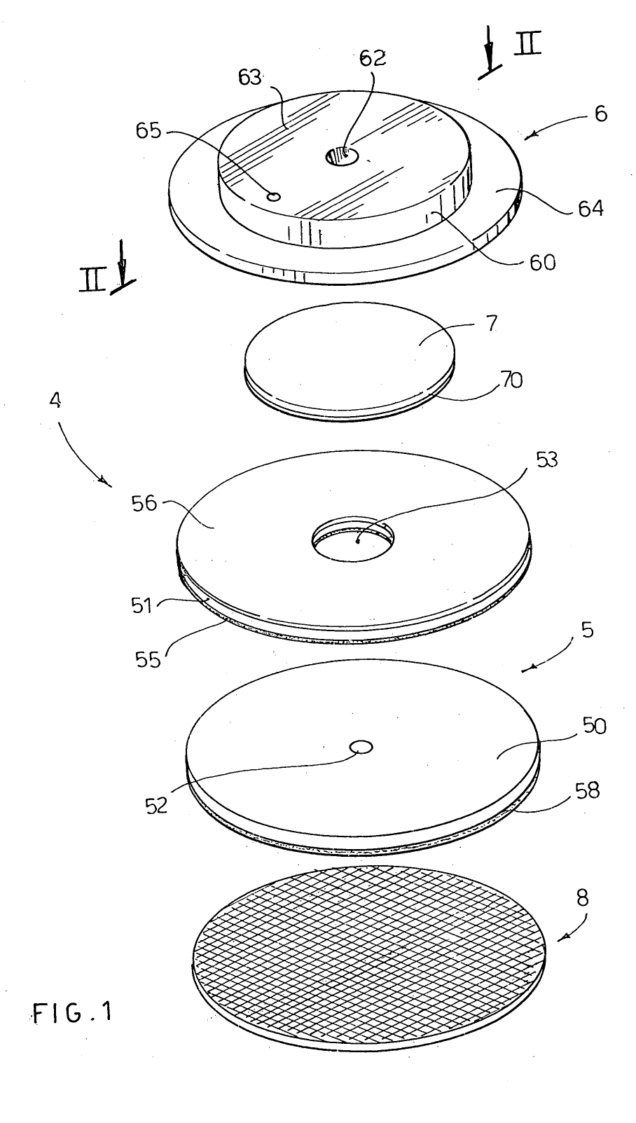

FIG. 1 is a diagrammatic exploded perspective view of a degassing valve according to the invention; and

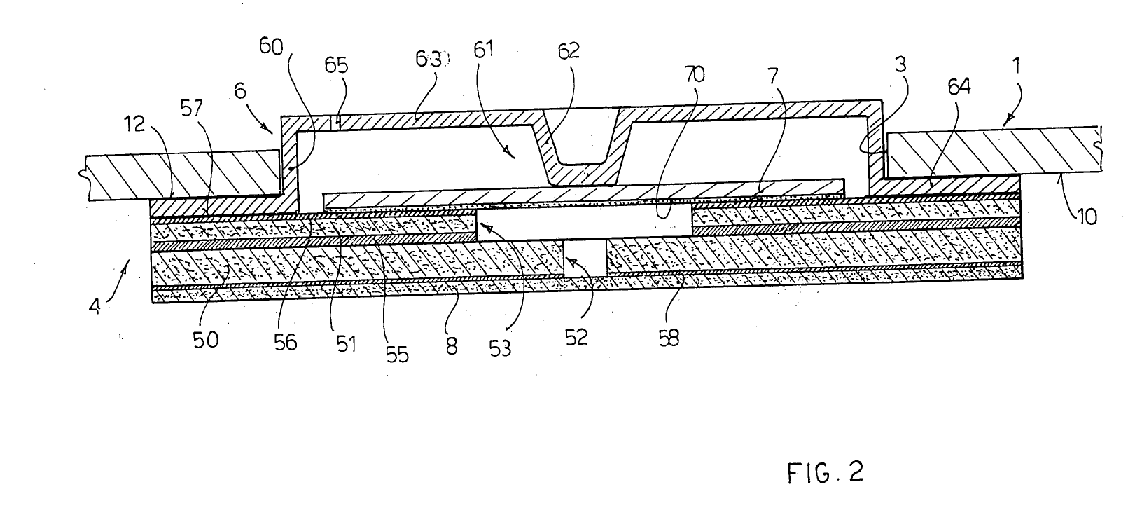

FIG. 2 is a diagrammatic axial sectional view taken along the plane II-II of FIG. 1, showing the valve assembled and mounted on a container, illustrated partially.

With reference to said figures, in FIG. 2 a container for aromatic products, in particular coffee, which can be flexible, semi-rigid, or rigid has been indicated generally with reference numeral 1.

In the example illustrated, the one-way valve according to the invention is provided in the top wall of the container, but it could be disposed on any side wall thereof. For this purpose, a hole 3 is formed in the wall, for example of cardboard or multi-layer material. The degassing valve, denoted as a whole with reference numeral 4, is mounted in said hole 3. The valve 4 is normally heat sealed or glued to the inner surface 10 of the top wall of the container in which the hole 3 is formed.

With reference also to FIG. 1, the degassing valve 4, the general structure of which can be considered substantially known, comprises:
a base plate or body 5,
a cap 6 designed to be mounted on the base plate 5,
a flexible diaphragm 7 interposed between the base plate 5 and the cap 6, and
a filter 8 designed to be disposed beneath the base plate 5.

The base plate 5 comprises two substantially disk-shaped plate elements 50, 51 having the same outside diameter, designed to be coupled together one on top of the other.

The bottom disk 50 of the base plate 5 has a central through hole 52 having a fairly small diameter, for example 2 mm. The top disk 51 of the base plate 5, on the other hand, has a central through hole 53 having a larger diameter than that of the hole 52 in the bottom disk 50. The diameter of the hole 53 with the larger diameter is about 7 mm, for example.

The diameter of the hole 52 preferably ranges from one-half to one-quarter of the diameter of the hole 53, which ranges from 4 to 9 mm.

The two disks 50, 51 of the base plate are preferably made of substantially rigid cardboard. A layer or film of heat-sealable plastic material 54, impermeable to synthetic oils, is applied to the upper surface of the top disk. Said surface layer 56 can be formed, for example, of a polyolefin and in particular of a polyethylene-based material.

The two disks, the top one 50 and the bottom one 51, are of a thickness ranging between 0.5 and 1.1 mm, preferably about 0.8 mm.

The two disks 50, 51 of the base plate 5 are coupled by means of a layer of glue 55, so that the two holes of different diameters 52, 53 are disposed coaxially to each other. The layer of glue 55 is preferably applied to the lower surface of the top disk 51, so that the area of the upper surface of the top disk 50 disposed around the small-diameter hole 52, is delimited by the large-diameter hole 53 of the top disk 51 not affected by the glue 55.

The base plate 5, rather than in two pieces 50, 51, could also be made in a single piece provided with two coaxial central holes 52, 53 of different diameters.

A filter 8 which serves to cover the smaller diameter hole 52 of the bottom disk 50 of the base plate is applied beneath the base plate 5. In this manner the filter 8 allows the passage of gases given off by the product inside the container, but does not allow the passage of solid particles of product.

The filter 8 advantageously consists of a filter paper having a thickness from 0.05 to 0.3 mm, preferably about 0.1 mm. Even if in the figures the surface and the shape of the filter 9 are substantially similar to those of the base plate 5, the filter 8 can have a different shape and surface, provided it completely covers the hole 52 with the smaller diameter.

The filter 8 is fixed to the lower surface of the bottom disk 50 of the base plate by means of a layer of glue 58 applied to the lower surface of the bottom disk 50. Alternatively, the filter 8 can be heat sealed to the lower surface of the bottom disk 50.

The diaphragm 7 is substantially disk-shaped, having a diameter larger than the diameter of the larger diameter hole 53 of the top disk and smaller than the outside diameter of the top disk 51 of the base plate.

The diaphragm 7 has an extremely reduced thickness, from 0.008 to 0.05 mm, preferably about 0.01 mm, and is made of flexible plastic material, such as PVC (polyvinyl chloride) for example. A synthetic oil 70 such as a silicone oil, for example, is applied to the lower surface of the diaphragm 7.

The diaphragm 7 is disposed in a central position on the surface layer of polyethylene 56 of the base plate 5, so as to cover the hole 53.

The cap 6 is fixed to the base plate 5 so as to contain the diaphragm 7 on its inside.

The cap 6 is substantially disk-shaped with an outside diameter substantially equal to that of the base plate 5. The cap 6 has a toroidal base plate or flange 64 from which rises centrally a cylindrical sleeve 60 which is closed by a bottom 63 so as to define on the inside a cylindrical chamber 61.

The sleeve 60 has an outside diameter slightly smaller than the diameter of the hole 3 in the wall of the container 1 and an inside diameter slightly larger than the diameter of the diaphragm 7. In this manner the sleeve 60 of the cap 6 can be inserted in the hole 3 of the container and the diaphragm 7 can be contained inside the chamber 61 of the tang of the cap 6.

A post 62 which abuts against the central wall of the diaphragm 7 protrudes centrally downward from the bottom 63 of the cap 6.

A small venting through hole 65 is formed on the bottom 63 of the cap 6.

The cap 6 is preferably made of metal material, such as aluminium for example, and is formed by drawing.

The inside surface of the toroidal base plate 64 of the cap is fixed to the layer of polyethylene 56 of the base plate 5 by means of heat sealing 57. The upper surface of the toroidal base plate 64 of the cap, on the other hand, is fixed to the inside surface layer 10 disposed around the hole 3 in the top wall of the container 1 by heat sealing 12.

It should be noted that the cap 6 has been made of metallic material that is a good heat conductor to facilitate the heat seals 57 and 12, respectively, on the layer of polyethylene 56 of the base plate and on the heat sealable layer 10 of the inner surface of the container 1.

It should further be noted that the surface layer of polyethylene 56 not only serves to allow heat sealing, but also serves to ensure a tight seal with the silicone oil 70 of the diaphragm, as well as to create an barrier impermeable to the silicone oil 70 which would otherwise be absorbed by the cardboard of the top disk 51, compromising the tight seal of the base plate 5.

Operation of the degassing valve 4 according to the invention will be described below.

When the product contained in the container develops gas, the gases generated pass through the filter 8 and enter the smaller diameter hole 52 of the first disk 50 of the base plate, accumulating inside the larger diameter hole 53 of the second disk 51, beneath the diaphragm 7.

The larger diameter hole 53 thus behaves as an expansion chamber in which the gases exert pressure from the bottom upward (with reference to FIG. 2) on the diaphragm 7. As a result the diaphragm 7 lifts peripherally being retained centrally by the post 62 of the cap 6. Consequently the gases pass into the chamber 61 of the cap 6 and exit into the atmosphere through the discharge hole 65 provided on the bottom 63 of the cap 6.

It is obvious that said valve 4 behaves as a one-way valve, since it allows the passage of gas only from the inside to the outside of the container 1 and not vice versa. Opening of the valve 4 is obtained by pressure exerted on the diaphragm 7 from the inside toward the outside, equal to about 20 cm of water column. On the other hand, the difference between closing and opening is obtained with a few centimetres, about 3-7. In other terms, the valve closes if the pressure falls beneath the values indicated above.

The different shape of the hole formed in the base plate, in particular the small diameter of the hole 52 formed in the bottom disk 50, gives the valve structure considerable stiffness.

Since the valve is extremely flat, the two different diameters of the holes 52, 53 prevent the filter paper 8, placed on the side of the smaller diameter hole 52, from coming into contact with the diaphragm 7, which would impair operation of the valve.

Numerous variations and modifications of detail within the reach of a person skilled in the art can be made to the present embodiment of the invention without thereby departing from the scope thereof as set forth in the appended claims.

1. A one-way degassing valve for airtight containers for products that develop gas comprising:
a base body provided with an inlet hole for the passage of gas,
a cap provided with a discharge hole for discharge of gas, designed to be coupled to said base body, and
a mobile diaphragm interposed between said base body and said cap to open/shut off the passage of gas from the inlet hole to the discharge hole, wherein said base body includes at least one flattened plate and said inlet hole comprises a first hole with a smaller diameter and a second hole with a larger diameter disposed beneath said mobile diaphragm so as to form an expansion chamber for the gases coming from the inside of the container.

2. A valve according to claim 1, further comprising a filter applied to said base body so as to cover said smaller diameter hole of the base body, such as to allow the passage of gas and retain the solid particles.

3. A valve according to claim 2, wherein said filter is made of filter paper and is applied to the surface of said base body by means of a layer of glue or heat sealing.

4. A valve according to claim 1, wherein said smaller diameter hole has a diameter from one-half to one-quarter of the diameter of the larger diameter hole.

5. A valve according to claim 4, wherein said diameter of said larger diameter hole is about 4 to 9 mm.

6. A valve according to claim 1, wherein said base body comprises a first plate provided with said smaller diameter hole and a second plate provided with said larger diameter hole coupled with each other so that the two holes of different diameters are disposed substantially coaxially to each other.

7. A valve according to claim 6, e ma, wherein said first and second plates of the basic base body are substantially disc-shaped and have substantially the same outer diameter.

8. A valve according to claim 6 wherein said first and second plates of the base body are made of stiff cardboard and are coupled together by means of a layer of glue.

9. A valve according to claim 6, wherein said first and second plates are of a thickness between about 0.5 and 1.1 mm, preferably about 0.8 mm.

10. A valve according to claim 9, wherein said first and second plates are of the same thickness.

11. A valve according to claim 1, wherein on the surface of said base body whereon said mobile diaphragm rests, a layer of heat-sealable plastic material is applied to allow heat-sealing of the cap.

12. A valve according to claim 1, wherein on the surface of said base body whereon the mobile diaphragm rests, a layer of plastic material impermeable to synthetic oils is applied and on the surface of said mobile diaphragm destined to come into contact with said layer of plastic material a synthetic oil able to ensure a seal with said layer of plastic material is applied.

13. A valve according to claim 12, wherein said layer of synthetic oil applied to the surface of the diaphragm is a silicone oil.

14. A valve according to 11, wherein said layer of plastic material applied to the surface of the base body is a polyethylene-based polyolefin.

15. A valve according to claim 1, wherein said diaphragm is substantially disk-shaped with a diameter larger than a diameter of said larger diameter hole in the base body.

16. A valve according to claim 1, wherein said diaphragm is made of PVC.

17. A valve according to claim 15 wherein said cap has a sleeve with a bottom defining a chamber within which said diaphragm is contained, there protruding from said bottom a post able to abut against a central portion of said diaphragm.

18. A valve according to claim 1, wherein said cap is made of aluminium by drawing.

19. A valve according to claim 1, wherein said cap is fixed to a wall of the container, around a hole, by heat sealing.

20. An airtight container for products that develop gases, wherein said container comprises a one-way degassing valve according to claim 1.
